(19) United States
(12) Patent Application Publication
(10) Pub. No.: US 2016/0358979 A1
(43) Pub. Date: Dec. 8, 2016

(54) OLED UNIT AND FABRICATION METHOD THEREOF, DISPLAY PANEL AND DISPLAY APPARATUS

(71) Applicant: BOE TECHNOLOGY GROUP CO., LTD., Beijing (CN)

(72) Inventors: CHANG YEN WU, Beijing (CN); GUANG YAN, Beijing (CN); XIANG WAN, Beijing (CN)

(73) Assignee: BOE Technology Group Co., Ltd., Beijing (CN)

(21) Appl. No.: 15/031,203

(22) PCT Filed: Sep. 17, 2015
(86) PCT No.: PCT/CN2015/089875

§ 371 Date: Apr. 21, 2016

(30) Foreign Application Priority Data
Feb. 10, 2015 (CN) 201510070011.1

(51) Int. Cl. H01L 27/32; H01L 51/50; H01L 51/56; H01L 51/52

(52) U.S. Cl. CPC H01L 27/326; H01L 51/5203; H01L 51/504; H01L 51/56; H01L 51/5056; H01L 51/5072; H01L 2227/323

(57) ABSTRACT

An Organic Light-emitting Diode (OLED) unit having a group of pixels is provided. The OLED unit includes a first electrode layer including a plurality of sub-electrodes, each of the sub-electrodes is corresponding to one of the group of pixels, respectively; a second electrode layer; and an electroluminescent layer including at least one light-emitting layer between the first electrode layer and the second electrode layer, wherein each light-emitting layer is corresponding to two sub-electrodes included in the first electrode layer, and a projection of the light-emitting layer on first electrode layer covers the two corresponding sub-electrodes.

### CROSS-REFERENCES TO RELATED APPLICATIONS

This PCT patent application claims priority of Chinese Patent Application No. 201510070011.1, filed on Feb. 10, 2015, the entire contents of which are incorporated by reference herein.

### FIELD OF THE INVENTION

The present invention generally relates to the field of display technologies and, more particularly, to OLED units and fabrication processes thereof, a display panel and a display apparatus.

### BACKGROUND

An Organic Light-emitting Diode (OLED) unit is a self-emitting device; and OLED units are major components of a display apparatus. For example, a display panel of a display apparatus is usually composed of a plurality of OLED units.

An OLED unit having a group of pixels includes an anode layer, an electroluminescent layer and a cathode layer. The electroluminescent layer is in between the anode layer and the cathode layer. The electroluminescent layer includes a plurality of light-emitting layers corresponding to the plurality of pixels, respectively. The anode layer includes a plurality of sub-anode layers; and each sub-anode layer is corresponding to one of the light emitting layers. The projection of the light emitting layer on the anode layer covers the corresponding sub-anode layer.

The fabrication process of an OLED unit may include, sequentially, forming an anode layer and an electroluminescent layer, respectively; performing an alignment on the anode layer and the electroluminescent layer to cause the projection of each light emitting layer of the electroluminescent layer to cover the sub-anode layer corresponding to the light emitting layer; and forming a cathode layer on the side of the electroluminescent layer away from the anode layer.

With the continuous increase of the resolution of a display panel, it may need to form more OLED units on a same size of a display panel. Thus, the area of the OLED units has become smaller and smaller. When the alignment is performed on the anode and the electroluminescent layer, transplacements may occur between the light emitting-layer and the corresponding sub-anode layer. The display panel composed of the OLED units with such transplacements may have a color mixing during displaying. The disclosed methods and systems are directed to at least partially alleviate one or more problems set forth above and other problems.

### BRIEF SUMMARY OF THE DISCLOSURE

On aspect of the present disclosure includes an Organic Light-emitting Diode (OLED) unit. The OLED unit comprises a first electrode layer including a plurality of sub-electrodes, each of the sub-electrodes is corresponding one of the group of pixels, respectively; a second electrode layer; and an electroluminescent layer including at least one light-emitting layer between the first electrode layer and the second electrode layer, wherein each light-emitting layer is corresponding to two sub-electrodes included in the first electrode layer, and a projection of the light-emitting layer on the first electrode layer overlaps with the two corresponding sub-electrodes.

Optionally, the projection of the light-emitting layer on the first electrode layer covers the corresponding sub-electrodes.

Optionally, the sub-electrode includes a transparent electrode close to the electroluminescent layer and a reflective electrode.

Optionally, thicknesses of the two transparent electrodes corresponding to the light-emitting layer are different.

Optionally, each group of pixels are corresponding to a first light-emitting layer and a second light-emitting layer; the first light-emitting layer is used for providing light to a first pixel and a second pixel; and the second light-emitting layer is used for providing light to a third pixel and a fourth pixel.

Optionally, a thickness of the transparent electrode corresponding to a pixel for emitting blue light is smaller than a thickness of the transparent electrode corresponding to a pixel for emitting green light.

Optionally, a thickness of the transparent electrode corresponding to a pixel for emitting green light is smaller than a thickness of the transparent electrode corresponding to a pixel for emitting red light.

Optionally, the thickness of the transparent electrode corresponding to a pixel for emitting green light is in a range of approximately 25 nm˜35 nm; the thickness of the transparent electrode corresponding to a pixel for emitting green light is in a range of approximately 45 nm˜55 nm; and the thickness of the transparent electrode corresponding to a pixel for emitting red light is in a range of approximately 85 nm˜95 nm.

Optionally, the electroluminescent layer further includes a hole transport layer; and an electron transport layer.

Optionally, the light-emitting layer is between the electron transport layer and the hole transport layer; and the hole transport layer is close to the first electrode layer; and the electron transport layer is close to the second electrode layer.

Optionally, a distance between the two sub-electrodes corresponding to the same light-emitting layer is in a range of approximately 0˜30 μm.

Another aspect of the present disclosure includes a method for fabricating an Organic Light-emitting Diode (OLED) unit. The method comprises providing a substrate; forming a first electrode layer including a plurality of sub-electrodes on the substrate; forming an electroluminescent layer including at least one light-emitting layer on the first electrode layer, wherein each light-emitting layer is corresponding to two of the sub-electrodes; and forming a second electrode layer over the substrate.

Optionally, a distance between the two sub-electrodes corresponding to a same light-emitting layer is in a range of approximately 0˜30 μm.

Optionally, the electroluminescent layer includes a first light-emitting layer and a second light-emitting layer; two sub-electrodes corresponding to the first light-emitting layers for emitting red light and the green light, respectively; and two sub-electrodes corresponding to the second light-emitting layer are emitting blue light and green light.

Optionally, the sub-electrode includes a transparent electrode and a reflective electrode.

Optionally, a thickness of the transparent electrode in the sub-electrode for emitting blue light is smaller than a thickness of the transparent electrode in the sub-electrode for emitting green light; and a thickness of the transparent electrode in the sub-electrode for emitting green light is smaller than a thickness of the transparent electrode in the sub-electrode for emitting red light.

Optionally, the thickness of the transparent electrode in the sub-electrode for emitting green light is in in a range of approximately 25 nm˜35 nm; the thickness of the transparent electrode in the sub-electrode for emitting green light is in a range of approximately 45 nm˜55 nm; and the thickness of the transparent electrode in the sub-electrode for emitting red light is in a range of approximately 85 nm˜95 nm.

Another aspect of the present disclosure includes a display panel comprising at least one disclosed Organic Light-emitting Diode (OLED) unit.

Another aspect of the present disclosure includes a display apparatus comprising at least one disclosed display panel.

According to the present disclosure, because one light-emitting layer may be corresponding to two sub-electrodes, the number of the light emitting layers in an OLED unit may be reduced; and the light-emitting area may be increased. Thus, the difficulties for aligning the light-emitting layer with the corresponding sub-electrodes may be reduced; and the color mixing phenomenon of a display panel may be avoided.

Other aspects of the present disclosure can be understood by those skilled in the art in light of the description, the claims, and the drawings of the present disclosure.

### BRIEF DESCRIPTION OF THE DRAWINGS

Drawings are used as a part of the disclosure to further illustrate the present disclosure. The drawings and following embodiments are used to further explain the present disclosure; and do not constitute limitations of the present disclosure. In the drawings:

FIG. 1 illustrates an exemplary OLED unit according to the disclosed embodiments;

FIG. 2 illustrates detailed structures of an exemplary OLED unit according to the disclosed embodiments;

FIG. 3 illustrates detailed structures of another exemplary OLED unit according to the disclosed embodiments;

FIG. 4 illustrates detailed structures of another exemplary OLED unit according to the disclosed embodiments;

FIG. 5 illustrates an exemplary fabrication process of an OLED unit according to the disclosed embodiment;

FIG. 6 illustrates a flow chart of an exemplary fabrication process of an OLED unit according to the disclosed embodiment;

FIG. 7 illustrates another exemplary OLED unit according to the disclosed embodiments; and

FIG. 8 illustrates a block diagram of an exemplary display apparatus according to the disclosed embodiments.

### DETAILED DESCRIPTION

Reference will now be made in detail to exemplary embodiments of the invention, which are illustrated in the accompanying drawings. The detailed descriptions only illustrate certain exemplary embodiments of the present invention, and are not intended to limit the scope of the present invention.

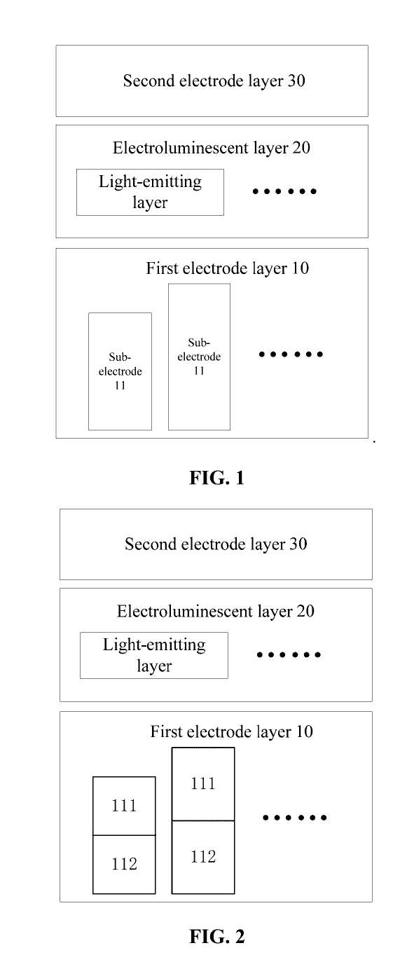

FIG. 1 illustrates an exemplary OLED unit according to the disclosed embodiments. As shown in FIG. 1, the OLED unit may include a first electrode layer 10 having a plurality of sub-electrodes 11, an electroluminescent layer 20, and a second electrode layer 30. The electroluminescent layer 20 may be placed between the first electrode layer 10 and the second electrode layer 30.

The electroluminescent layer 20 may include at least one light-emitting layer; and each light-emitting layer may be corresponding to two of the sub-electrodes 11. That is, the first electrode layer 10 may include two sub-electrodes 11 corresponding to a light-emitting layer. The projection of the light-emitting layer on the first electrode layer 10 may cover the two corresponding sub-electrodes.

Thus, in the OLED unit, one light-emitting layer may be corresponding to two sub-electrodes 11, the number of the light emitting layers in the OLED unit may be reduced; and the light-emitting area may be increased. Thus, the difficulty for aligning the light-emitting layers and the corresponding sub-electrodes may be reduced; and the color mixing of a display panel having such an OLED unit may be avoided.

When the OLED unit is emitting light, the first electrode layer 10 and the second electrode layer 30 may be connected with the anode and the cathode of a power source, respectively. The first electrode layer 10 may generate holes; and the holes may be transported to the light-emitting layer. The second electrode 30 may generate electrons; and the electrons may also be transported to the light-emitting layer. The electrons and the holes in the light-emitting layer may combine; and high energy excitons may be generated. Because the high energy excitons may be unstable, it may be easy for the high energy excitons to transit to low energy excitons and release energy. When the energy is released, light with a wavelength in a certain range may be emitted. For each pixel of a certain color, the sub-electrode may select light with a wavelength in a certain range from the emitted light; and the light with a wavelength in the certain range may be emitted from the OLED unit.

The second electrode layer 30 may be the cathode of the OLED unit. The second electrode layer 30 may have desired conductivity, desired chemical stability; and desired morphological stability, etc. Further, the second electrode layer 30 is a semi-transparent layer and a semi-reflective layer. Further, the first electrode layer 10 and the second electrode layer 30 may form a micro-cavity to change the color of the light emitted from the light-emitting layer by selecting the light with a wavelength in the certain range.

The second electrode layer 30 may be made of any appropriate material, such as metal material or metal alloy, etc. The metal material may include Ag, Al, Mg, or Li, etc. The metal alloy may include MgAg, MgAl, or MgCa, etc.

The electroluminescent layer 20 may include at least one light-emitting layer. The light emitted by the light-emitting layer may be a mixture of different colors, i.e, a color spectrum. Each sub-electrode 11 may select the corresponding light with a specific color emitted by the light-emitting layer by a certain method. The light with specific colors corresponding to the two sub-electrodes 11 should be included the light emitted by the light-emitting layer. For example, for the two sub-electrodes 11 corresponding to the light-emitting layer, if one is corresponding to green light, the other is corresponding to blue light, and the light emitted by light-emitting layer may at least include green light and blue light.

The sub-electrodes 11 with different thicknesses may be corresponding to different colors of light. The wavelength of the light corresponding to a sub-electrode 11 may be proportional to the thickness of the sub-electrode 11. That is, the thicker the sub-electrode 11 is, the longer of the wavelength of the light corresponding to the sub-electrode 11 is. As shown in FIG. 1, the thicknesses of the two sub-electrodes 11 corresponding to the light-emitting layer may be different. Thus, the two sub-electrodes 11 corresponding to the light-emitting layer may choose two different colors of light from the light emitted by the light-emitting layer.

Red light, green light and blue light are three basic colors of light. In one embodiment, each sub-electrode 11 may be set to be corresponding to one basic type of color. Thus, by controlling the thicknesses of the different sub-electrodes 11 of the OLED unit, the OLED unit may emit one or more basic type of colors; and the plurality of the basic types of colors may be mixed to emit different colors of light other than red light, green light and blue light.

The light-emitting layer may be made of any appropriate material, such as fluorescent material, or phosphor material, etc. Each light-emitting material may emit light with a different color. Thus, for each light-emitting layer and the two corresponding sub-electrodes 11, the light-emitting layer may include at least the light-emitting material which is able to emit light with the colors corresponding to the two sub-electrodes 11. For example, the light-emitting layer is corresponding to two sub-electrodes 11, one sub-electrode 11 is corresponding to a green light, and the other is corresponding to a blue light, the light-emitting layer may include at least the light-emitting material which is able to emit a green light, and the light emitting material which is able to emit a blue light.

In one embodiment, for each light-emitting layer, the distance between two sub-electrodes 11 corresponding to a same light-emitting layer may be in a range of approximately 0˜30 μm. For example, the distance between the two sub-electrodes 11 corresponding to the light-emitting layer may be approximately 5 μm, 10 μm, 15 μm, 20 μm, 25 μm, or 30 μm, etc. If the distance is relatively small, the volume of the OLED unit may be reduced; and the number of OLED units in per unit area of the display panel may be increased. The pixel density of the display panel may be increased. For example, if the sub-electrodes 11 are aligned with a pentile arrangement, i.e., RGBG, the pixels per inch (ppi) may be increased by 1.3 time. Further, one light-emitting layer may be corresponding to two sub-electrodes 11, a mask layer may be used to form two sub-electrodes 11. Thus, the ppi may be further increased by two times.

In one embodiment, the projection of each light-emitting layer on the first electrode layer 10 covers the two corresponding sub-electrodes 11. Other number of sub-electrodes 11 may also be used. For example, one light emitting layer may be corresponding to more than two sub-electrodes 11. Because the light-emitting layer is corresponding to two sub-electrodes 11, the total number of the light-emitting layers in the OLED unit may be reduced; and the light-emitting area may be increased. Therefore, the alignment difficulties between the light-emitting layer and the sub-electrodes 11 may be reduced; and the color mixing of the display panel having such OLED units may be avoided.

FIG. 2 illustrates the detailed structure of each of sub-electrodes 11 included in the first electrode layer 10 according to the disclosed embodiments. The sub-electrode 11 may include a transparent electrode 111 and a reflective electrode 112. In one embodiment, the transparent electrode is a transparent conductive oxide electrode (TCO), such as an indium-tin oxide (ITO) transparent electrode, etc. The transparent electrode 111 may be in between the corresponding light-emitting layer and the reflective electrode 112; and may be corresponding to a color type. The transparent electrode 111 may be connected with the anode of a power source. When the transparent electrode is connected with the anode of the power source, it may generate holes. The holes may be transported to the light-emitting layer corresponding to the sub-electrodes 11. The reflective electrode may be able to reflect light to the second electrode layer 30. That is, a micro-cavity may be formed by the reflective 112 electrode and the second electrode layer 30.

The light-emitting layer corresponding to the sub-electrodes 11 may emit light. The light may irradiate on the transparent electrode 111 of the sub-electrode 11. Further, by using the transparent electrode with different thickness, different micro-cavities may have different thickness. Thus, each micro-cavity may select the corresponding color type of light from the light emitted by the light-emitting layer; and emit the selected color type of light through the micro-cavity formed.

In one embodiment, the transparent electrode 111 is corresponding to a basic light color type. When the basic color type of light corresponding to the transparent electrode 111 is a green light, the thickness of the transparent electrode may be in a range of approximately 45 nm˜55 nm. For example, the thickness may be approximately 45 nm, 50 nm, or 55 nm, etc. When the basic color type of light corresponding to the transparent electrode 111 is a blue light, the thickness of the transparent electrode 111 may be in a range of approximately 25 nm˜35 nm. For example, the thickness may approximately 25 nm, 30 nm, or 35 nm, etc. When the basic color type of light corresponding to the transparent electrode 111 is a red light, the thickness of the transparent electrode 111 may be in range of approximately 85 nm˜95 nm. For example, the thickness may be approximately 85 nm, 90 nm, or 95 nm, etc.

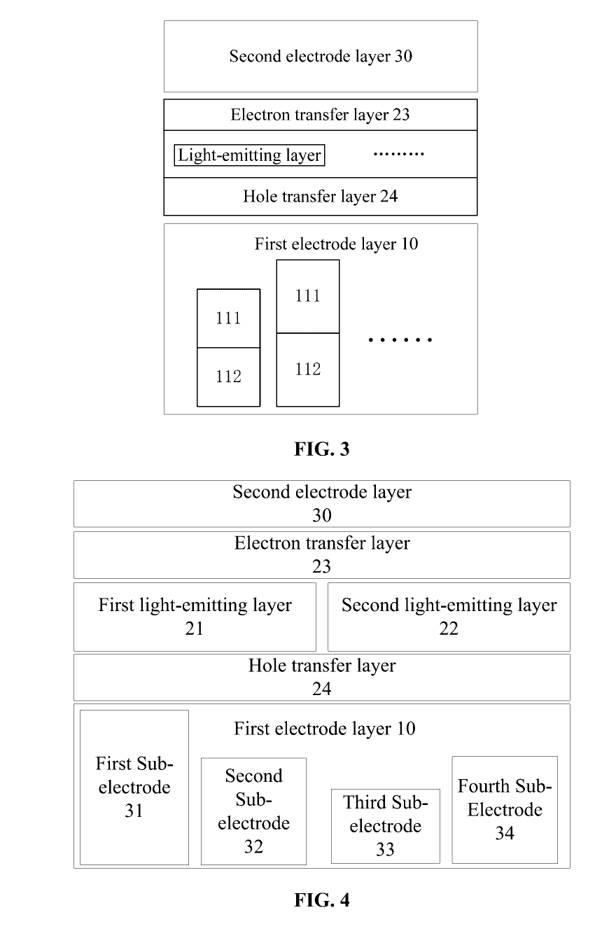

Further, as shown in FIG. 3, the electroluminescent layer 20 may also include an electron transport layer 23 and a hole transport layer 24. At least one light-emitting layer may be in between the electron transport layer 23 and the hole transport layer 24. The electrode transport layer 23 is close to the second electrode layer 30; and the hole transport layer 24 is close to the first electrode layer 10.

The electron transport layer 23 is used for receiving the electrons from the second electrode layer 30; and transporting the electrons to the light-emitting layer. The electron transport layer 23 may have a relatively high electron conductivity; and may be able to rapidly transport the electrons from the second electrode layer 30 to the light-emitting layer. Thus, the electron transport speed may be increased.

The electrode transport layer 23 may be made of any appropriate material, such as metal organic complex, or certain 1, 10-Phenanthroline monohydrate material, etc. The thickness of the electron transport layer 23 may be in a range of approximately 20 nm˜40 nm. For example, the thickness of the electron transport layer 23 may be approximately 20 nm, 25 nm, 30 nm, 35 nm, or 40 nm, etc.

The hole transport layer 24 may be used to receive the holes injected by the first electrode layer 10; and transport the received holes to the light-emitting layer. The hole transport layer 24 may have a relatively high hole conductivity; and may be able to rapidly transport the holed generated by the first electrode layer 10 to the light-emitting layer. Thus, the hole transport speed may be increased.

The hole transport layer 24 may be made of any appropriate materials, such as triarylamine material, etc. The thickness of the hole transport layer 24 may be in a range of approximately 50 nm˜120 nm. For example, the thickness of the hole transport layer 24 may be in a range of approximately 50 nm, 60 nm, 70 nm, 80 nm, 90 nm, 100 nm, 110 nm, or 120 nm, etc.

Optionally, in order to increase the resolution of the display panel, it may need the OLED unit to emit light array with a RGBG . . . sequence. That, it may require the sub-electrodes 11 of the OLED unit to emit a row of light with the sequence: red light (R), green light (G), blue light (B) and green light (G), . . . . Such an alignment may be referred as a side-by-side scheme.

For example, the electroluminescent layer 20 may include two light-emitting layers: a first light-emitting layer and a second light-emitting layer. Two sub-electrodes 11 corresponding to the first light-emitting layer may be used for selecting a red light and a green light from the light emitted from the first light-emitting layer, and to emit the red light and the green light. Another two sub-electrodes 11 corresponding to the second light emitting layer may be used for selecting a blue light and a green light from the light emitted by the second light-emitting layer, and emit the blue light and the green light. Therefore, it may only need two light-emitting layers to obtain the RGBG row alignment. Comparing with the existing RGBG alignment, which utilizes four light-emitting layers and four slot masks, the present structure may only need two slit masks. Thus, the production cost may be reduced. Further, the power consumption may be reduced.

For example, as shown in FIG. 4, the electroluminescent layer 20 includes two light-emitting layers, which are the first light-emitting layer 21 and the second light-emitting layer 22. The first light-emitting layer 21 and the second light-emitting layer 22 may be disposed in the electroluminescent layer 20 side-by-side.

The first light-emitting layer 21 is corresponding to a first sub-electrode 31 and a second sub-electrode 32 in the first electrode layer 10. The first sub-electrode 31 and the second sub-electrode 32 are corresponding to a first pixel A and a second pixel B, respectively. The thickness of the transparent electrode of the first sub-electrode 31 and the thickness of the transparent electrode of the second sub-electrode 32 may be different. The thickness of the transparent electrode in the first sub-electrode 31 may be approximately 90 nm; and the light corresponding to such a thickness is red. The thickness of the transparent electrode in the second sub-electrode 32 may be approximately 50 nm; and the light corresponding to such a thickness is green.

The second light-emitting layer 22 is corresponding to a third sub-electrode 33 and a fourth sub-electrode 34 in the first electrode layer 10. The third sub-electrode 33 and the fourth sub-electrode 34 are respectively corresponding to a third pixel C and a fourth pixel D. The thickness of the transparent electrode of the third sub-electrode 33 corresponding to the third pixel C and the thickness of the transparent electrode of the fourth sub-electrode 34 corresponding to the fourth pixel D may be different. The thickness of the transparent electrode of the third sub-electrode 33 may be approximately 30 nm; and the light corresponding to such a thickness is blue. The thickness of the transparent electrode of the fourth sub-electrode 34 may be approximately 50 nm; and the light corresponding to such a thickness is green.

The first light-emitting layer 21 may be able to emit light, and irradiate on the first sub-electrode 31 and the second sub-electrode 32. The transparent electrode of the first sub-electrode 31 and the second electrode layer 30 may form a micro-cavity. The micro-cavity may select the corresponding red light from the light emitted by the first light-emitting layer 21. The transparent electrode of the second sub-electrode 32 may select the corresponding green light from the light emitted by the first light-emitting layer 21 in a similar way.

The second light-emitting layer 22 may be able to emit light, and irradiate on the third sub-electrode 33 and the fourth sub-electrode 34. The transparent electrode of the third sub-electrode 33 and the second electrode layer 30 may form a micro-cavity. The micro-cavity may select the corresponding blue light from the light emitted by the second light-emitting layer 22. The transparent electrode of the fourth sub-electrode 34 may select the corresponding green light from the light emitted by the second light emitting layer 22 in a similar way.

Therefore, as shown in FIG. 4, the OLED unit may emit the row of light with a sequence of RGBG. That is, the row of the light includes red light (R), green light (G), blue light (B) and green light (G). In certain other embodiments, ABCD may be in a form of RGBY or RGBW, etc. That is the row of the light include red light (R), green light (G), blue light (B) and yellow light (Y), or the row of the light include red light (R), green light (G), blue light (B) and white light (W)

In certain other embodiments, the first sub-electrode 31, the second sub-electrode 32, the third sub-electrode 33 and the fourth sub-electrode 34 may be arranged into two rows or four rows, etc. In still certain other embodiments, an OLED unit may include at least one sub-electrode 11 for emitting red light, two sub-electrodes 11 for emitting green light, or one sub-electrode 11 for emitting blue light. For example, a sub-electrode 11 may include two groups of RGBG sub-electrodes 11; and the arrangement may be RRGGBBGG, etc. In still certain other embodiments, the number of the sub-electrodes 11 may be other appropriate value and the arrangement may be different.

In one embodiment, as shown in FIG. 4, a group of pixels may include a first light-emitting layer 21 and a second light-emitting layer 22. The group of pixels may also include the first sub-electrode 31, the second sub-electrode 32, the third sub-electrode33 and the fourth sub-electrode 34. The first light-emitting layer 21 is corresponding to the first sub-electrode 31 and the second sub-electrode 32. The first sub-electrode 31 may be corresponding to a red pixel; and the second sub-electrode 32 may be corresponding to a green pixel. The second light-emitting layer 22 is corresponding to the third sub-electrode 33 and the fourth sub-electrode 34. The third sub-electrode 33 may be corresponding to a blue pixel; and the fourth sub-electrode 34 may be corresponding to a green pixel. In certain other embodiments, a plurality of such pixels may be included in a display panel; and the plurality of pixels may be arranged into a matrix or an array of pixels.

Further, a display panel may be formed by the disclosed OLED units. The display panel may include a plurality of at least one type of above-disclosed OLED units. In the display panel, because light emitting layer may be corresponding to two sub-electrodes, the number of the light emitting layers in the OLED unit may be reduced; and the light emitting area may be increased. Thus, the difficulties for aligning the light emitting layer with the corresponding sub-electrodes may be reduced; and the color mixing phenomenon of the display panel may be avoided. Further, the ppi may be increased and the power consumption may be reduced.

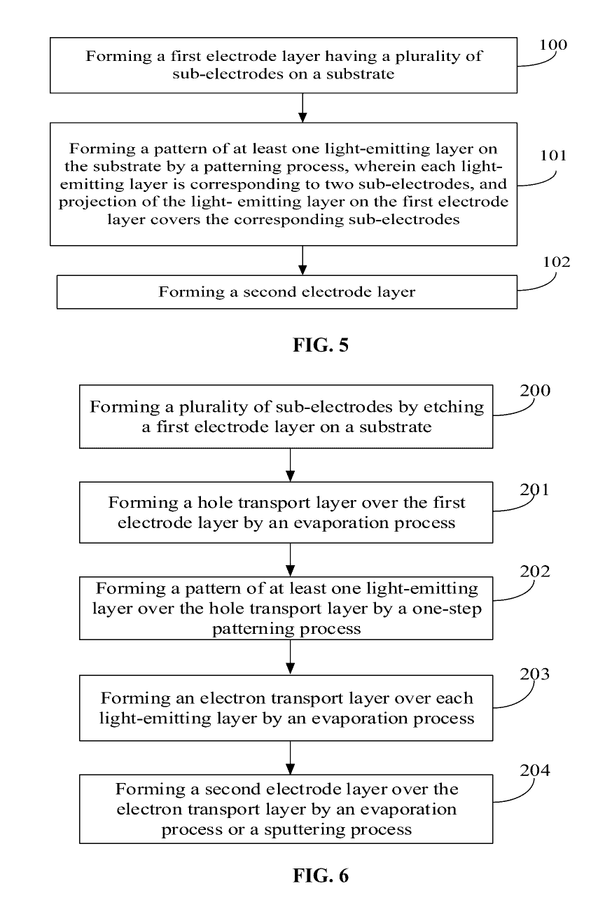

FIG. 5 illustrates an exemplary fabrication process of an OLED unit described in the previous embodiments. As shown in FIG. 5, the process may include following steps.

Step 100, forming a first electrode layer on a substrate, wherein the first electrode layer may include a plurality of sub-electrodes. The substrate may be made of any appropriate material, such as glass, or flexible material, etc. The flexible material may include one or more of polyester and polyimide, etc. In one embodiment, the substrate is transparent glass. The transparent glass may aid the OLED unit to have a desired light-emitting efficiency; and also increase the firmness of the OLED unit.

Step 101, forming a pattern including at least one light-emitting layer on the substrate by a patterning process, wherein each light-emitting layer is corresponding to two sub-electrodes in the second electrode layer, the projection area of each light-emitting layer in the first electrode layer covers each corresponding sub-electrode. The patterning process may be any appropriate process. In one embodiment, the pattering process may be a photolithography process and an evaporation process.

Step 102, forming a second electrode layer on the substrate.

In the present fabrication process of an OLED unit, because a light-emitting layer may be corresponding to two sub-electrodes, the number of light emitting-layers in the OLED unit may be reduced; and the light-emitting area may be increased. Thus, the difficulty for aligning the light-emitting layer and the sub-electrodes may be reduced; and the color mixing phenomenon of the display panel may be avoided. Further, the ppi of the display panel may be increased and the power consumption may be reduced.

A detailed description of an exemplary fabrication process of the OLED unit illustrated in FIG. 4 is illustrated in FIG. 6. As shown in FIG. 6, the process may include the following steps.

Step 200, forming a plurality of sub-electrodes 11 on the substrate by etching a first electrode layer 10. Each of sub-electrode 11 may include a transparent electrode 111 and a reflective electrode 112. Similarly, the substrate may be made of any appropriate material, such as glass, or flexible material, etc. The flexible material may include one or more of polyester and polyimide, etc. In one embodiment, the substrate is transparent glass. The transparent glass may aid the OLED unit to have a desired light-emitting efficiency; and also increase the firmness of the OLED unit.

Each of the light-emitting layers may be corresponding to two sub-electrodes 11 in the first electrode layer 10. The distance between the two sub-electrodes 11 may be in a range of approximately 0˜30 μm. For example, the distance between two sub-electrodes 11 corresponding to a light-emitting layer may be approximately 5 μm, 10 μm, 15 μm, 20 μm, 25 μm, or 30 μm. Thus, the distance between the two sub-electrodes 11 may be relatively small, and the number of the OLED units disposed in per unit area of the display panel may be increased; and the pixel density of the display panel may be increased.

The thicknesses of the transparent electrode 111 of any two adjacent sub-electrodes 11 in the first electrode layer 10 may be different. The transparent electrode and the subsequently formed second electrode layer may form a micro-cavity and each micro-cavity may be corresponding to a certain color type of light. The thickness of a micro-cavity may be proportional to the wavelength of the corresponding color type of light. When light irradiates the sub-electrode 11, the micro-cavity may be able to select the corresponding color type of light, emit the color type of light; and filter out other light.

In order to cause the OLED unit to emit a row of light with RGBG sequence, it may need form four sub-electrodes 11 in the first electrode layer 10 on the substrate. For example, as shown in FIG. 4, the four sub-electrodes are a first sub-electrode 31, a second sub-electrode 32, a third sub-electrode 33 and a fourth sub-electrode 34. By controlling the thicknesses of the first sub-electrode 31, the second sub-electrode 32, the third sub-electrode 33 and the fourth sub-electrode 34, e.g., not all same, the first sub-electrode 31, the second sub-electrode 32, the third sub-electrode 33 and the fourth sub-electrode 34 may form four micro-cavities with different thickness, and the four micro-cavities be corresponding to different color types of light.

In one embodiment, the first sub-electrode 31 is corresponding to red light; the second sub-electrode 32 is corresponding to green light; the third sub-electrode 33 is corresponding to blue light; and the fourth sub-electrode 34 is corresponding to green light.

Further, as shown in FIG. 6, the process may also include Step 201, forming a hole transport layer 24 over the first electrode layer 10. The hole transport layer 24 may be formed by any appropriate process. In one embodiment, the hole transport layer 24 is formed by an evaporation process. The thickness of the hole transport layer 24 may be in a range of approximately 50 nm˜120 nm.

Further, as shown in FIG. 6, the process may also include Step 202, forming at least one light-emitting layer over the hole transport layer 24. The light-emitting layer may be formed by any appropriate process. In one embodiment, the light-emitting layer is formed by a one-step patterning process. Each light-emitting layer may be corresponding to two sub-electrodes in the first electrode layer 10; and the projection of the light-emitting layer on the first electrode layer 10 may overlap with the two corresponding sub-electrodes.

In one embodiment, the number of the light-emitting layers is two. As shown in FIG. 4, the two light-emitting layers are the first light-emitting layer 21 and the second light-emitting layer 22.

The first light-emitting layer 21 may be corresponding to a first sub-electrode 31 and a second sub-electrode 31. The projection region of the first light-emitting layer 21 in the second electrode layer 30 may overlap with the first sub-electrode 31 and the second sub-electrode 32. Optionally, the projection may include the first sub-electrode 31 and the second sub-electrode 32.

The second light-emitting layer 22 may be corresponding to a third sub-electrode 33 and a fourth sub-electrode 34. The projection of the second light-emitting layer 22 on the first electrode layer 10 may overlap with the third sub-electrode 33 and the fourth sub-electrode 34. Optionally, the projection may cover the third sub-electrode 33 and the fourth sub-electrode 34.

In one embodiment, one light-emitting layer is corresponding to two sub-electrodes. Thus, comparing with aligning one light-emitting layer with one sub-electrode region, the alignment of one light-emitting layer against two s may be more precise; and the color mixing may be avoided.

Further, as shown in FIG. 6, the process may also include Step 203, forming an electron transport layer 23 over each light-emitting layer. The electron transport layer 23 may be formed by any appropriate process. In one embodiment, the electron transport layer 23 is formed by an evaporation process. The thickness of the electron transport layer 23 may be in a range of approximately 20 nm˜40 nm.

Further, as shown in FIG. 6, the process may also include Step 204, forming a second electrode layer 30 over/on the electron transport layer 23. The second electrode layer 30 may be used as a cathode. The thickness of the second electrode layer 30 may be in a range of approximately 80 nm˜120 nm.

The first electrode layer 10 may be formed by any appropriate process, such as an evaporation process, or a sputtering process. In one embodiment, the pressure of the evaporation process may be in a range of approximately 1×10⁻⁵Pa˜9×10⁻³Pa.

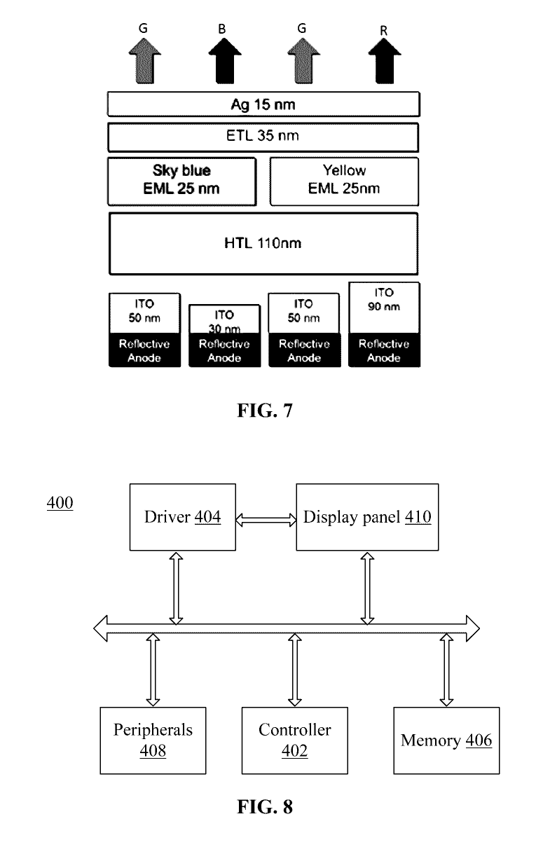

Thus, an OLED unit may be formed. The OLED unit may be used as one pixel. FIG. 7 illustrates an exemplary OLED unit.

As shown in FIG. 7, the OLED unit includes an Ag layer with a thickness of 15 nm configured as a second electrode; an electron transporting layer (ETL) with a thickness of 35 nm; a first light-emitting layer (EML) emitting sky blue light with a thickness of 25 nm; a second light-emitting layer (EML) emitting yellow light with a thickness of 25 nm; a hole transport layer (HTL) with a thickness of 110 nm; and four sub-electrodes. Each sub-electrode includes an ITO layer and a reflective anode.

The light emitting from the EML layer may have a certain light spectrum. By changing the thickness of the ITO layer, each pixel may emit a certain color light. For example, when the thickness of the ITO layer corresponding to the sky blue EML is 50 nm, the corresponding pixel may emit green light; when the thickness of the ITO layer corresponding to the sky blue EML the sky blue EML is 30 nm, the corresponding pixel may emit blue light; when the thickness of the ITO layer corresponding to the yellow EML is 50 nm, the corresponding pixel may emit green light; and when the thickness of the ITO layer corresponding to the yellow EML is 90 nm, the corresponding pixel may emit red light. The light intensity of such light is desirable.

Further, a display apparatus may be formed by the disclosed processes, methods, and structures. The display apparatus may include at least one disclosed display panel. The display panels may be disposed as a matrix; and interconnected by any appropriate other devices and structures.

FIG. 8 illustrates the block diagram of an exemplary display apparatus 400 incorporating certain disclosed display panels. The display apparatus 400 may be any appropriate device or component with certain display function. As shown in FIG. 8, the display apparatus includes a controller 402, driver circuitry 404, memory 406, peripherals 408, and at least one display panel 410. Certain devices may be omitted and other devices may be included.

The controller 402 may include any appropriate processor or processors, such as a general-purpose microprocessor, digital signal processor, and/or graphic processor. The memory 406 may store computer programs for implementing various processes, when executed by the controller 402.

Peripherals 408 may include any interface devices for providing various signal interfaces. Peripherals 408 may also include any appropriate communication module for establishing connections through wired or wireless communication networks.

The driver circuitry 404 may include any appropriate driving circuits to drive the display panel 410. The display panel 410 may include one or more of the disclosed display panels. During operation, the display panel 410 may be provided with image signals by the controller 402 and the driver circuitry 404 for display.

Because the display panel may include the disclosed OLED units, the color mixing of the display panel may be avoided. Therefore, the quality of the display apparatus having the plurality of such display panels may be enhanced.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

1-19. (canceled)

20. An Organic Light-emitting Diode (OLED) unit having a group of pixels, comprising:
a first electrode layer including a plurality of sub-electrodes, each of the sub-electrodes is corresponding one of the group of pixels, respectively;
a second electrode layer; and
an electroluminescent layer including at least one light-emitting layer between the first electrode layer and the second electrode layer, wherein each light-emitting layer is corresponding to two of the sub-electrodes.

21. The OLED unit according to claim 20, wherein:
the projection of the light-emitting layer on the first electrode layer covers the corresponding sub-electrodes.

22. The OLED unit according to claim 20, wherein:
the sub-electrode includes a transparent electrode close to the electroluminescent layer and a reflective electrode.

23. The OLED unit according to claim 20, wherein: thicknesses of the two transparent electrodes corresponding to the light-emitting layer are different.

24. The OLED unit according to claim 20, wherein:
each group of pixels are corresponding to a first light-emitting layer and a second light-emitting layer;
the first light-emitting layer is used for providing light to a first pixel and a second pixel; and
the second light-emitting layer is used for providing light to a third pixel and a fourth pixel.

25. The OLED unit according to claim 20, wherein:
a thickness of the transparent electrode corresponding to a pixel for emitting blue light is smaller than a thickness of the transparent electrode corresponding to a pixel for emitting green light.

26. The OLED unit according to claim 20, wherein:
a thickness of the transparent electrode corresponding to a pixel for emitting green light is smaller than a thickness of the transparent electrode corresponding to a pixel for emitting red light.

27. The OLED unit according to claim 20, wherein:
the thickness of the transparent electrode corresponding to a pixel for emitting green light is in a range of approximately 25 nm˜35 nm;
the thickness of the transparent electrode corresponding to a pixel for emitting green light is in a range of approximately 45 nm˜55 nm; and
the thickness of the transparent electrode corresponding to a pixel for emitting red light is in a range of approximately 85 nm˜95 nm.

28. The OLED unit according to claim 20, wherein the electroluminescent layer further includes:
a hole transport layer; and
an electron transport layer.

29. The OLED unit according to claim 27, wherein:
the light-emitting layer is between the electron transport layer and the hole transport layer;
the hole transport layer is close to the first electrode layer; and
the electron transport layer is close to the second electrode layer.

30. The OLED unit according to claim 20, wherein:
a distance between the two sub-electrodes corresponding to the same light-emitting layer is in a range of approximately 0˜30 μm.

31. A method for fabricating an Organic Light-emitting Diode (OLED) unit, comprising:
providing a substrate;
forming a first electrode layer including a plurality of sub-electrodes on the substrate;
forming an electroluminescent layer including at least one light-emitting layer on the first electrode layer, wherein each light-emitting layer is corresponding to two of the sub-electrodes; and
forming a second electrode layer over the substrate.

32. The method according to claim 31, wherein:
a distance between the two sub-electrodes corresponding to a same light-emitting layer is in a range of approximately 0˜30 μm.

33. The method according to claim 32, wherein:
the electroluminescent layer includes a first light-emitting layer and a second light-emitting layer;
two sub-electrodes corresponding to the first light-emitting layers for emitting red light and the green light, respectively; and
two sub-electrodes corresponding to the second light-emitting layer for emitting blue light and green light.

34. The method according to claim 29, wherein:
the sub-electrode includes a transparent electrode and a reflective electrode.

35. The method according to claim 34, wherein:
a thickness of the transparent electrode in the sub-electrode for emitting blue light is smaller than a thickness of the transparent electrode in the sub-electrode for emitting green light; and
a thickness of the transparent electrode in the sub-electrode for emitting green light is smaller than a thickness of the transparent electrode in the sub-electrode for emitting red light.

36. The method according to claim 33, where:
the thickness of the transparent electrode in the sub-electrode for emitting green light is in in a range of approximately 25 nm˜35 nm;
the thickness of the transparent electrode in the sub-electrode for emitting green light is in a range of approximately 45 nm˜55 nm; and
the thickness of the transparent electrode in the sub-electrode for emitting red light is in a range of approximately 85 nm˜95 nm.

37. A display panel comprising at least one Organic Light-emitting Diode (OLED) unit according to claim 20.

38. A display apparatus comprising at least one display panel according to claim 37.
